(19) United States
(12) Patent Application Publication
(10) Pub. No.: US 2026/0346309 A1
(43) Pub. Date: Nov. 5, 2026

(54) DEVICE FOR REMOVING SEALANT FROM WASTE SOLAR PANEL

(71) Applicant: WON KWANG S&T CO., LTD., Incheon (KR)

(72) Inventors: Sang Hun LEE, Incheon (KR); Jun Kee KIM, Seoul (KR); Tae Heun LEE, Incheon (KR); Cheong Min NOH, Incheon (KR); Se Joong OH, Yongin-si, Gyeonggi-do (KR); Seung Seop JO, Incheon (KR); Do Yun LEE, Incheon (KR)

(21) Appl. No.: 19/123,777

(22) PCT Filed: Nov. 8, 2023
(86) PCT No.: PCT/KR2023/017831

§ 371 Date: Apr. 24, 2025

(30) Foreign Application Priority Data
Nov. 8, 2022 (KR) 10-2022-0148186

(51) Int. Cl. B09B 3/35; B09B 101/15; B26D 3/28; H10F 19/80; H10F 71/00

(52) U.S. Cl. CPC B09B 3/35; B26D 3/28; H10F 19/80; H10F 71/137; B09B 2101/15

(57) ABSTRACT

A waste solar panel sealant removing apparatus is provided. the sealant removing apparatus comprises a frame; a transfer unit installed on the frame and configured to transfer the waste solar panel in a horizontal direction; a pressing unit that descends from above the transfer unit and presses the waste solar panel to secure it; and a blade unit comprising a first blade and a second blade, wherein the first blade is in close contact with the waste solar panel and moves along an edge of the waste solar panel to scrape and remove the sealant attached to its surface, and the second blade is arranged at the rear of the first blade, moves along the edge of the waste solar panel, and removes residual sealant remaining after passing the first blade.

### TECHNICAL FIELD

The present invention relates to a technology for disassembling waste solar panels whose service life has expired so that they can be recycled, and more particularly, to a waste solar panel sealant removing apparatus capable of removing sealant and foreign substances attached to a glass plate of a waste solar panel.

This invention was developed through the following R&D support project of the Republic of Korea:
Project ID: 2022003170
Project Number: 2022003170007
Government Department: Ministry of Environment
Project Management Institution: Korea Environmental Industry & Technology Institute
Research Program Name: Green Innovation Enterprise Growth Support Program (Commercialization)
Research Project Name: Development and Commercialization of Resource Circulation Process Technology for Waste Solar Panels
Contribution Ratio: 1/1
Performing Organization: WONKWANG S&T Co., Ltd.
Research Period: Apr. 1, 2022~Dec. 31, 2022

### BACKGROUND ART

The efficiency of photovoltaic power generation has been greatly improved through continuous technological development. Technical advancements related to energy conversion, such as improvements in solar cells and panel structures, and progress in panel deployment and linkage technologies (e.g., energy storage management technology) have created synergy and are being applied to industries in various forms.

When photovoltaic power generation is applied on a large scale, the number of solar panels used can also increase. Since photovoltaic systems adjust power generation by increasing or decreasing modular units such as solar panels, more panels are used as power generation increases.

When the service life of the solar cells within a solar panel has ended, it becomes necessary to replace or discard the panel. Although solar panels are relatively easy to manage, their structural complexity increases the number of processes required during disposal. One major process in disposing of solar panels is the separation of the glass plate and the film layer (which includes the cells).

In particular, in the process of reusing the glass plate, technologies that scrape off the film layer (a multilayer structure comprising solar cells, encapsulants, back sheets, etc., attached to the glass plate), such as by using scrapers, may be used. For example, refer to Korean Patent Publication No. 10-2021-0094258. However, if sealant or other foreign substances remain on the surface of the glass plate, the pressure from the scraper may be unevenly distributed, leading to damage or breakage of the glass plate.

There has not been an adequate solution to such problems in the prior art, and thus a technical alternative has been needed. Related technology includes Korean Patent Publication No. 10-2021-0094258.

### DISCLOSURE

### Technical Problem

The technical problem to be solved by the present invention is to provide a technology that enables the disassembly of waste solar panels so that they can be recycled. More particularly, the present invention provides a waste solar panel sealant removing apparatus capable of removing sealant and foreign substances attached to the glass plate of a waste solar panel.

The technical problems of the present invention are not limited to those mentioned above, and other technical problems not mentioned will be clearly understood by those skilled in the art from the following description.

### Technical Solution

According to the present invention, a waste solar panel sealant removing apparatus, comprises: a frame; a transfer unit installed on the frame and configured to transfer the waste solar panel in a horizontal direction; a pressing unit that descends from above the transfer unit and presses the waste solar panel to secure it; and a blade unit comprising a first blade and a second blade, wherein the first blade is in close contact with the waste solar panel and moves along an edge of the waste solar panel to scrape and remove the sealant attached to its surface, and the second blade is arranged at the rear of the first blade, moves along the edge of the waste solar panel, and removes residual sealant remaining after passing the first blade.

Wherein, the first blade and the second blade may be configured such that at least one of the following—the angle formed between each blade and the surface of the waste solar panel, or the depth to which the waste solar panel is pressed—is formed differently between the first blade and the second blade.

Wherein, the transfer unit may comprise a first transfer unit composed of a plurality of transfer rollers for transferring the waste solar panel in a first direction, and at least one second transfer unit configured to transfer the waste solar panel in a second direction perpendicular to the first direction.

Wherein, the second transfer unit may comprise a transfer means for transferring the waste solar panel in the second direction, and a lifting means for moving the transfer means up and down so as to raise the transfer means to a position higher than the top of the transfer rollers or lower than the top of the transfer rollers.

The waste solar panel sealant removing apparatus may further comprise: a plurality of first stopper units that are installed on both sides of the first transfer unit, wherein at least a portion of each first stopper unit is movable in the second direction to support the lateral sides of the waste solar panel in the second direction.

Wherein, each first stopper unit may comprise a first support portion for supporting the side of the waste solar panel and an actuating portion for expanding or contracting the first support portion in the second direction, with the actuating portion separating the first support portion from the waste solar panel when the blade unit removes the sealant.

The waste solar panel sealant removing apparatus may further comprise: a plurality of second stopper units for supporting the lateral sides of the waste solar panel in the first direction, each second stopper unit comprising a rotation shaft arranged parallel to the second direction, a second support portion coupled to the rotation shaft and configured to support the side of the waste solar panel as the rotation shaft rotates, and a driving unit for rotating the rotation shaft.

Wherein, each second stopper unit may rotate the rotation shaft to separate the second support portion from the waste solar panel when the blade unit removes the sealant.

Wherein, four blade units may be independently arranged at each edge of the waste solar panel such that two of the blade units located at adjacent edges move along edges arranged in a ‘ [symbol] ’ or ‘ [symbol] ’ shape to remove sealant, and thereafter the remaining two blade units move along edges arranged in a ‘ [symbol] ’ or ‘ [symbol] ’ shape to remove sealant.

Wherein, after the first transfer unit and the second transfer unit transfer the waste solar panel in one direction so that the blade units move along edges arranged in a ‘ [symbol] ’ or ‘ [symbol] ’ shape to remove sealant, the first transfer unit and the second transfer unit then may move the waste solar panel in a diagonal direction so that the blade units move along edges arranged in a ‘ [symbol] ’ or ‘ [symbol] ’ shape to remove sealant.

Wherein, the blade unit may further comprise a third blade that is arranged at the rear of the second blade and moves along the edge of the waste solar panel to remove residual sealant remaining after passing the second blade, and wherein the first, second, and third blades are configured such that the angle formed with the surface of the waste solar panel gradually decreases.

Wherein, the waste solar panel may be arranged such that the glass plate contacts the transfer unit and the film layer contacts the pressing unit, and may further comprise a trimmer unit disposed on the upper side of the waste solar panel and configured to move along an edge of the waste solar panel to remove an end portion of the film layer.

### Advantageous Effects

According to the present invention, the surface of the glass plate of the waste solar panel can be made uniform prior to the delamination process. In particular, sealant (such as adhesive) or other foreign substances that were applied to bond the glass plate to the frame can be rapidly and effectively removed, especially near the edge of the glass plate. The present invention enables simultaneous processing of multiple edges even when the specifications and sizes of the waste solar panels vary, thus enhancing process efficiency. The multi-blade structure allows cleaner sealant removal, reducing the number of processing steps. Therefore, the present invention helps to make the surface of the glass plate uniform and effectively prevents damage to the glass plate during the delamination process.

### DESCRIPTION OF DRAWINGS

FIG. 1 illustrates a process layout using a waste solar panel sealant removing apparatus according to one embodiment of the present invention.

FIG. 2 is a perspective view of the sealant removing apparatus of FIG. 1.

FIG. 3 is an exploded view showing the main components of the sealant removing apparatus of FIG. 2.

FIG. 4 is a side view of the sealant removing apparatus of FIG. 3.

FIG. 5 is a plan view of the sealant removing apparatus of FIG. 2.

FIG. 6 is a front view of the sealant removing apparatus of FIG. 2.

FIG. 7 is a plan view of the sealant removing apparatus of FIG. 2 with the upper structure removed.

FIG. 8 is a plan view illustrating the panel feeding operation of the waste solar panel in the apparatus of FIG. 7.

FIG. 9 includes a plan view of the first positioning operation of the waste solar panel using the apparatus of FIG. 7 and a partial cross-sectional view of the apparatus of FIG. 2.

FIG. 10 includes a plan view and partial cross-sectional view showing the sealant removing and trimming operations after the first positioning operation using the apparatus of FIGS. 7 and 2.

FIG. 11 includes a plan view of the second positioning operation of the waste solar panel using the apparatus of FIG. 7 and a partial cross-sectional view of the apparatus of FIG. 2.

FIG. 12 includes a plan view and partial cross-sectional view showing the sealant removing and trimming operations after the second positioning operation using the apparatus of FIGS. 7 and 2.

### MODE FOR INVENTION

The advantages and features of the present invention and methods for achieving them will become apparent with reference to the embodiments described in detail below, together with the accompanying drawings. However, the present invention is not limited to the embodiments disclosed below and may be implemented in various other forms. The following embodiments are provided merely to ensure a complete disclosure of the present invention and to fully convey the scope of the invention to those skilled in the art. The present invention is only defined by the appended claims. Throughout the entire specification, the same reference numerals refer to the same components.

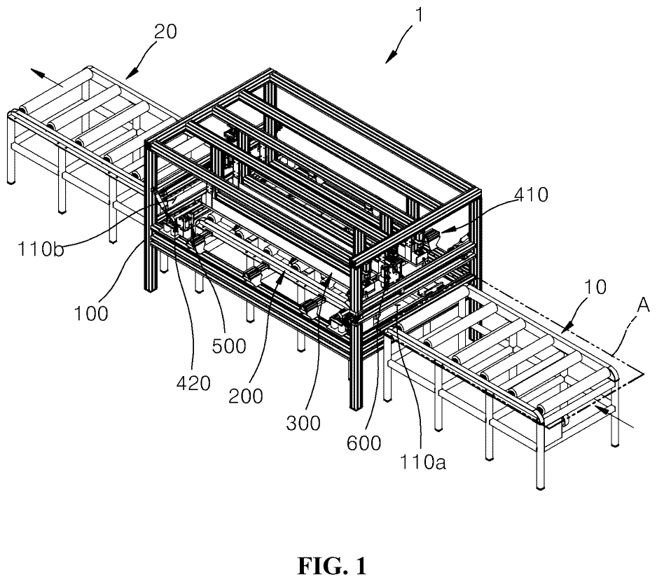

Hereinafter, the waste solar panel sealant removing apparatus according to the present invention will be described in detail with reference to FIGS. 1 to 12.

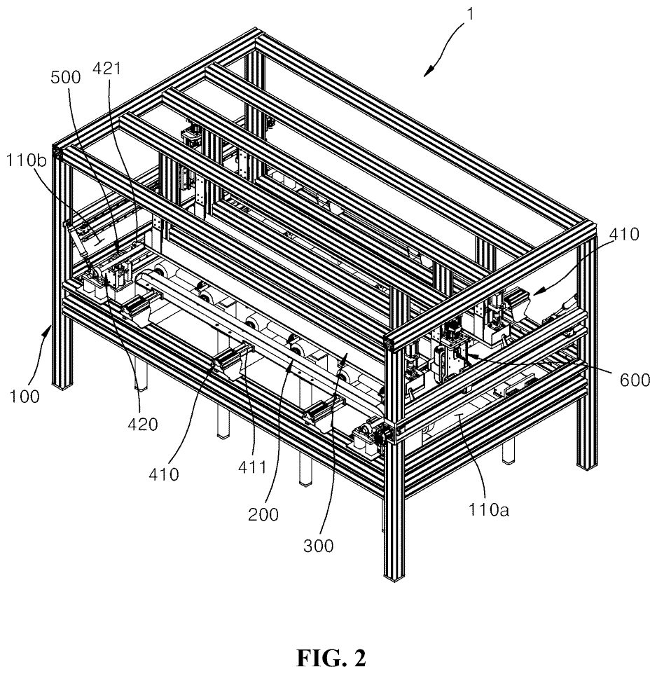

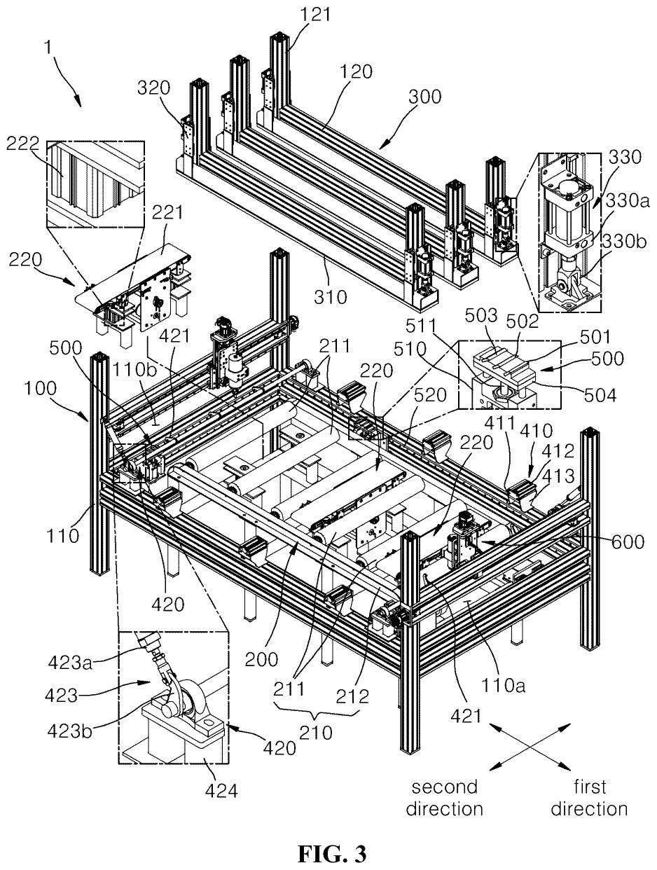

FIG. 1 illustrates a process layout using a waste solar panel sealant removing apparatus according to one embodiment of the present invention. FIG. 2 is a perspective view of the sealant removing apparatus of FIG. 1. FIG. 3 is an exploded view showing the main components of the sealant removing apparatus of FIG. 2.

Referring to FIGS. 1 to 3, the sealant removing apparatus (1) according to the present invention comprises a blade unit (refer to 500 in FIG. 3) that is movable in a straight line. The blade unit (500) is arranged in close contact with the waste solar panel (refer to A in FIG. 1) and moves along an edge of the waste solar panel to remove residual sealant and other foreign substances.

The blade unit (500) is formed with a multi-blade structure. For example, the first blade (refer to 501 in FIG. 3) and the second blade (refer to 502 in FIG. 3) are formed with different angles and/or pressing depths relative to the surface of the waste solar panel so that they can contact the same point on the waste solar panel at different angles and/or depths to remove residual sealant and other foreign substances.

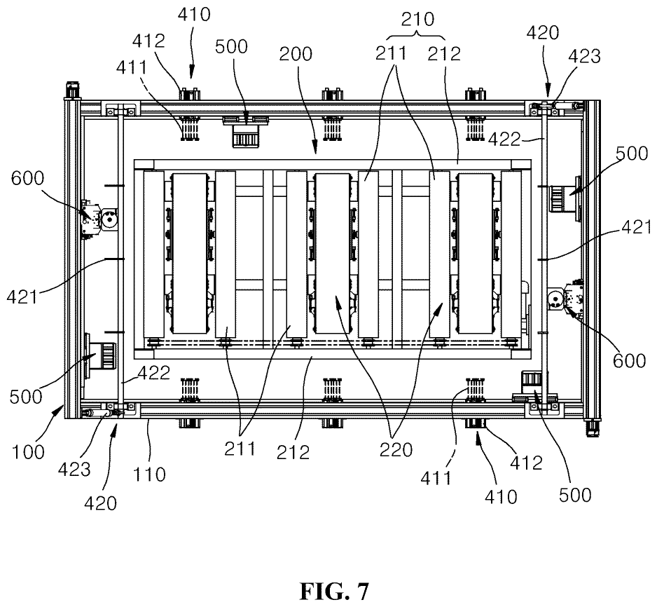

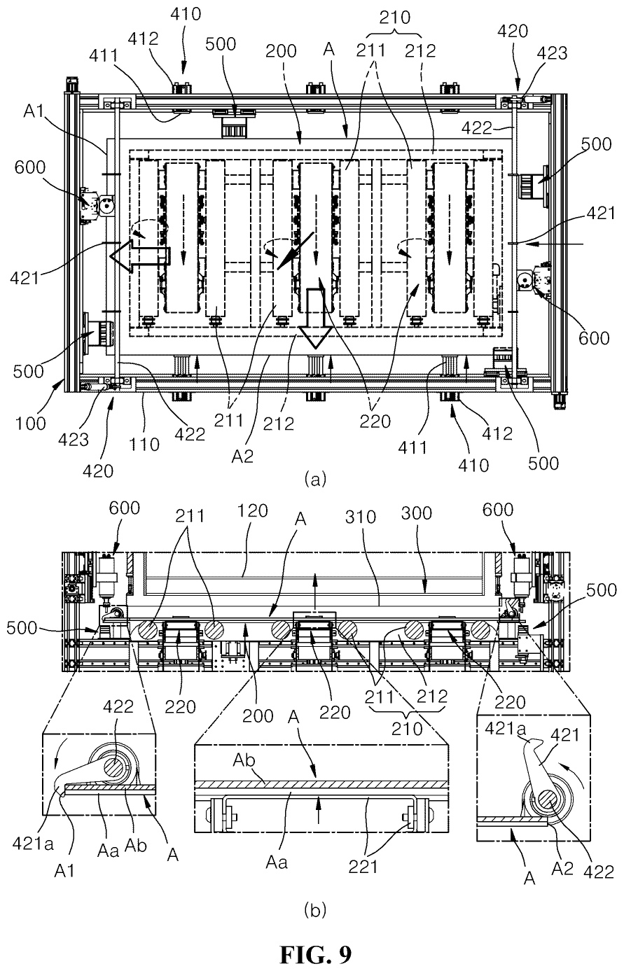

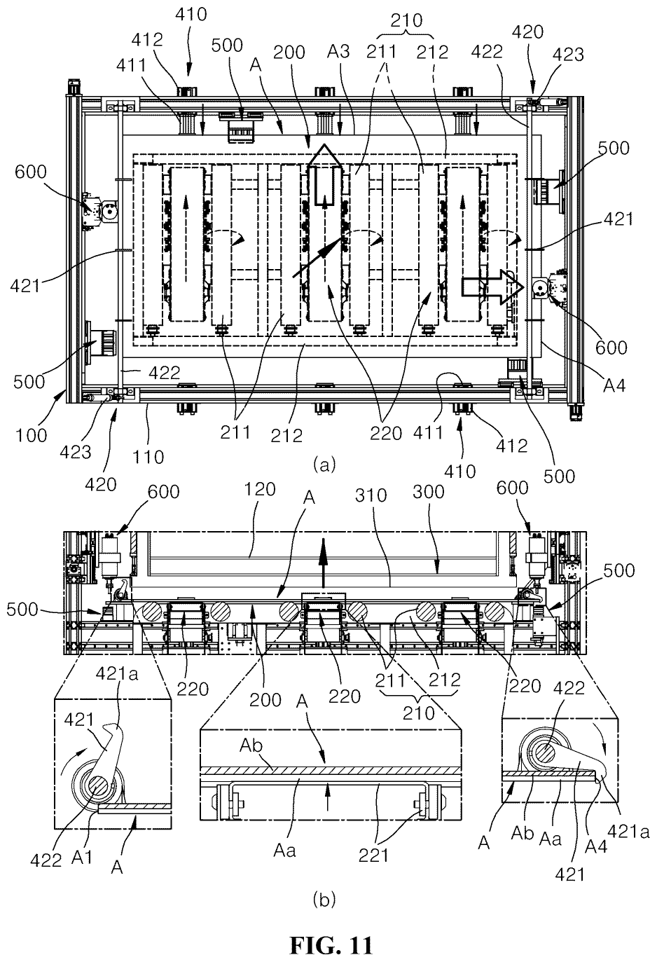

In the present invention, the blade unit (500) is arranged at the four edges of the waste solar panel (refer to the plan view in FIG. 7). Thus, multiple edges can be worked on simultaneously. In particular, because the present invention enables precise adjustment of the working position of the waste solar panel in a diagonal direction (refer to FIGS. 9 and 11), simultaneous processing of these edges (at least two edges concurrently) is possible even if the waste solar panel has different dimensions.

The sealant removing apparatus (1) of the present invention is configured as follows. The sealant removing apparatus (1) comprises a frame (100); a transfer unit (200) installed on the frame and configured to transfer the waste solar panel (refer to A in FIG. 1) in a horizontal direction; a pressing unit (300) that descends from above the transfer unit and presses the waste solar panel to secure it; and a blade unit (500) comprising a first blade and a second blade, wherein the first blade (refer to 501 in FIG. 2) is in close contact with the waste solar panel and moves along an edge of the waste solar panel to scrape and remove the sealant attached to its surface, and the second blade (refer to 502 in FIG. 2) is arranged at the rear of the first blade, moves along the edge of the waste solar panel, and removes residual sealant remaining after passing the first blade.

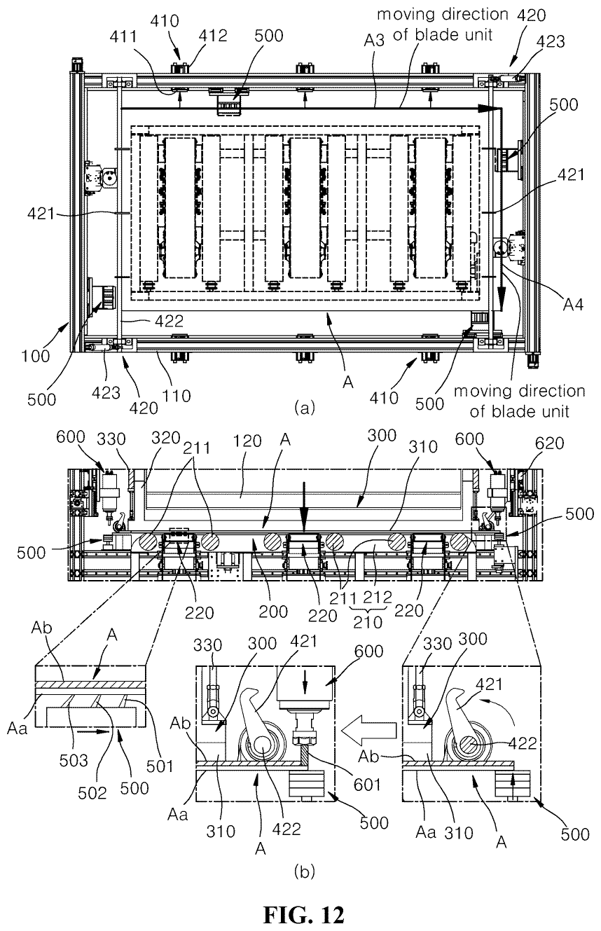

In one embodiment of the present invention, the first blade (501) and the second blade (502) are configured such that at least one of the following—the angle formed between each blade and the surface of the waste solar panel, or the depth to which the waste solar panel is pressed—is formed differently between the first blade and the second blade (refer to the enlarged view in FIG. 12).

Further, the transfer unit (200) may comprises a first transfer unit (210) composed of a plurality of transfer rollers (211) for transferring the waste solar panel in a first direction (refer to 210 in FIG. 3) and at least one second transfer unit (220) configured to transfer the waste solar panel in a second direction which is perpendicular to the first direction (refer to 220 in FIG. 3).

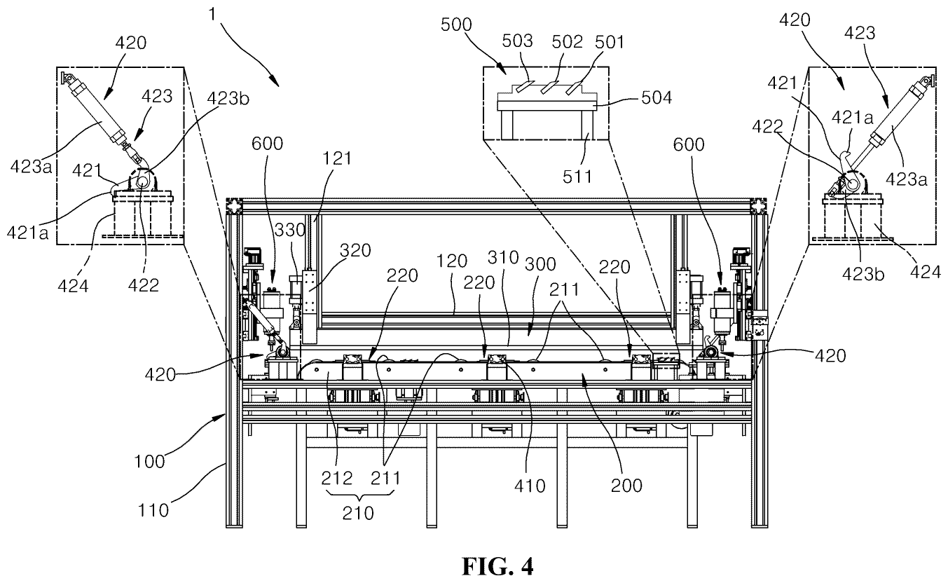

Additionally, a plurality of first stopper units (refer to 410 in FIG. 3) are installed on both sides of the first transfer unit (210), wherein at least a portion of each first stopper unit is movable in the second direction to support the lateral sides of the waste solar panel in that direction. Further, a plurality of second stopper units (refer to 420 in FIGS. 3 and 4) may be included for supporting the lateral sides of the waste solar panel in the first direction. Each second stopper unit includes a rotation shaft (422 in FIG. 3) arranged parallel to the second direction, a second support portion (421 in FIG. 3) coupled to the rotation shaft and configured to support the side of the waste solar panel as the rotation shaft rotates, and a driving unit (423 in FIG. 3) for rotating the rotation shaft.

Based on this embodiment of the present invention, the configuration and the effects of operation of the present invention will now be described in greater detail.

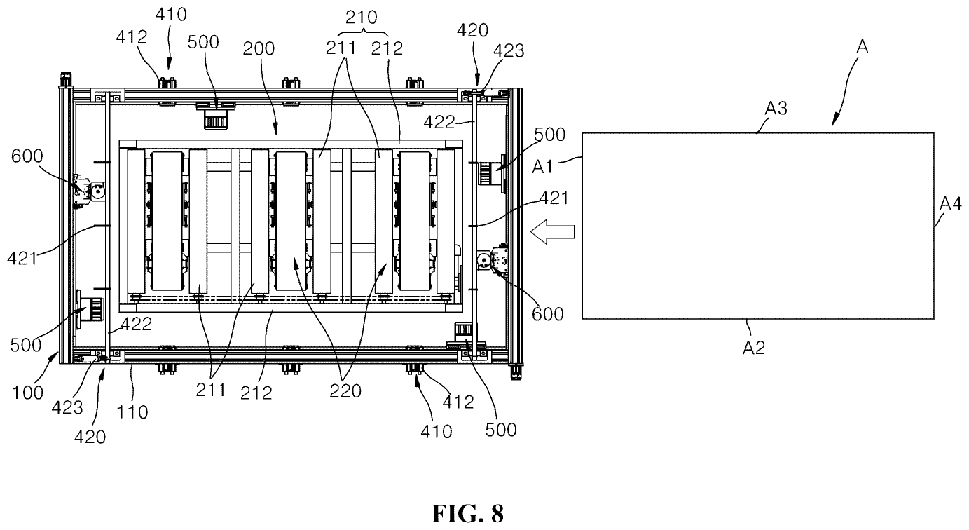

Referring first to FIG. 1, a brief description of the process layout of the sealant removing apparatus (1) is provided. The sealant removing apparatus (1) is used in the disassembly process of waste solar panels. In the process, the glass plate of the waste solar panel (refer to Aa in FIG. 9) is recovered without being shattered. The sealant removing apparatus (1) can be used in an intermediate stage before the peeling process that separates the film layer (refer to Ab in FIG. 12) from the waste solar panel (refer to A in FIG. 1), after a process for disassembling an external frame (not shown) that was coupled to the four edges (refer to A1 to A4 in FIG. 8) of the waste solar panel. The sealant removing apparatus (1) is used to remove the sealant (such as adhesive applied for fixing the external frame) and various foreign substances attached to the edges of the waste solar panel, particularly on the front glass plate (refer to Aa in FIG. 12), prior to the peeling process.

For this purpose, as shown in FIG. 1, a front entry conveyor (10) and a discharge conveyor (20) can be provided on the front (right side in FIG. 1) and rear (left side in FIG. 1) of the sealant removing apparatus (1), respectively. The waste solar panel (A) supplied to the sealant removing apparatus (1) is in a state where the external frame has been disassembled and can be supplied into the sealant removing apparatus (1) via the entry conveyor (10).

The frame (100) of the sealant removing apparatus (1) may be provided with an inlet (110a) open toward the entry conveyor (10) and an outlet (110b) open toward the discharge conveyor (20). In this manner, the sealant removing apparatus (1) receives the waste solar panel and removes the residual sealant (such as adhesive applied for fixing the external frame) and various foreign substances remaining on the front of the waste solar panel (A) before passing it to the subsequent process.

Referring to FIGS. 2 and 3, the structure of the sealant removing apparatus (1) is described in more detail. As shown in FIG. 2, the sealant removing apparatus (1) may be formed as a structure supported by a frame (100). The frame (100) may be formed by combining a lower structure and an upper structure in order to effectively support the sealant removing apparatus (1). For example, the frame (100) may include a bed (refer to 110 in FIG. 3) as its lower structure and an upper bridge (refer to 120 in FIG. 3) as its upper structure.

The upper bridge (120) shown in FIG. 3 is illustrated with its upper frame removed. The aforementioned inlet (110a) and outlet (110b) may be provided at the front and rear of the bed (110), which forms the lower structure. The upper bridge (120) is installed to support and position the pressing unit (300) on top of the bed (110). The upper structure of the frame (100), which includes the upper bridge (120), may be coupled to the lower structure (bed (110)) by welding or other methods. In this manner, the frame (100) may be formed.

The transfer unit (200) is installed on the frame (100) and transfers the waste solar panel in a horizontal direction. As shown in FIGS. 2 and 3, the transfer unit (200) may be arranged in the lower structure of the frame (100). The horizontal direction may include a first direction and a second direction. Both the first and second directions of the present invention are horizontal (e.g., perpendicular to gravity) and these may be directions lying on the surface of the waste solar panel (see A in FIG. 1). As depicted in FIG. 3, the first and second directions on the surface of the waste solar panel (A) may be mutually perpendicular. For example, the first and second directions may coincide with the directions of two mutually perpendicular edges of the waste solar panel.

Referring again to FIG. 3, the transfer unit (200) comprises a first transfer unit (210) that transfers the waste solar panel in the first direction, and a second transfer unit (220) that transfers the waste solar panel in the second direction, which is perpendicular to the first direction. The first transfer unit (210) is composed of a plurality of transfer rollers (211), and the second transfer unit (220) is arranged in the longitudinal direction of the transfer rollers (211) between them.

The first transfer unit (210) may be formed with a structure in which a plurality of transfer rollers (211) are spaced apart in the horizontal direction. The transfer rollers (211) may be interconnected by a chain, belt (not shown), or the like so that their rotation is synchronized. The transfer rollers (211) may be exposed, with the second transfer unit (220) arranged between them. In one embodiment, the first transfer unit (210) may be formed by having a plurality of transfer rollers (211) rotatably coupled to a horizontal support (212).

As shown in FIG. 3, the second transfer unit (220) may include transfer means (221) for transferring the waste solar panel (A) in the second direction, and a lifting means (222) for moving the transfer means (221) upward or downward so as to raise the transfer means (221) to a position above the top of the transfer rollers (211) or lower than the top of the transfer rollers (211) (see the separately illustrated second transfer unit on the left in FIG. 3).

In other words, the second transfer unit (220) comprises a lifting means (222) for variably adjusting the height of the transfer means (221). The transfer means (221) has a variable height due to the lifting means. For example, the transfer means (221) may be formed as a second-direction conveyor that transfers objects in the second direction, and its height may also be changed by the lifting means. The transfer means (221) is coupled to the lifting means (222)—a telescopic structure incorporating, for example, a cylinder—so that the entire assembly may move vertically.

Thus, the second transfer unit (220) is arranged between the transfer rollers (211) of the first transfer unit (210) and may move to a position above or below the top of the transfer rollers (211). With this structure, the waste solar panel may be moved by the transfer rollers (211) of the first transfer unit (210) or by the transfer means (221) of the second transfer unit (220). Since the transfer direction of the transfer rollers (211) is the first direction and the transfer direction of the transfer means (221) is the second direction (which is perpendicular to the first), the waste solar panel can be driven in a diagonal direction by combining these motions (see FIGS. 9 and 11). The specific operating process will be described in further detail later.

The second transfer unit (220) may also be supported by the frame (100) and a plurality of them may be arranged between the transfer rollers (211). The transfer means (221) of the second transfer unit (220) may be arranged in the longitudinal direction of the transfer rollers (211) of the first transfer unit (210). In addition to a belt-formed conveyor, the transfer means (221) may also be formed with rollers (for example, rollers arranged perpendicular to the transfer rollers) or the like.

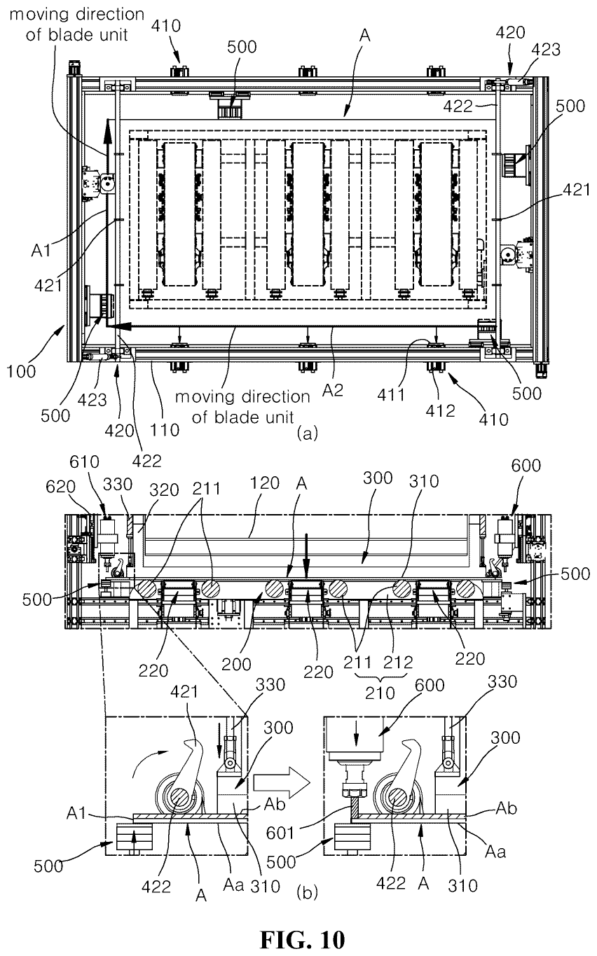

The pressing unit (300) is arranged on top of the transfer unit (200). As shown in FIGS. 2 and 3, the pressing unit (300) may be installed on the upper bridge (120) of the frame (100). The pressing unit (300) is capable of vertical movement; thus, when necessary, it descends from above the transfer unit (200) to press and secure the waste solar panel (see (b) of FIG. 10).

For example, the pressing unit (300) may include a slider (320) that is slidably coupled to the upper bridge (120), a pressing plate (310) arranged in the horizontal direction at the lower end of the slider (320), and a lifting drive unit (330) for raising and lowering the pressing plate (310). The slider (320) may be coupled to a vertical bar (121) of the upper bridge (120) so as to be capable of vertical movement.

Since the pressing plate (310) is the portion that contacts and presses the waste solar panel, a cushioning member (for example, formed of an elastic material such as rubber) may be arranged as needed. The lifting drive unit (330) may include, for example, a cylinder (330a) fixed to the upper bridge (120) and a connecting rod (330b) that connects the cylinder (330a) to the pressing plate (310). Thus, the pressing plate (310) may be raised and lowered by the telescopic action of the cylinder (330a).

However, since the lifting drive unit may also be formed by arranging a linear drive structure other than a cylinder in the vertical direction, the form of the lifting drive unit in the present embodiment is not particularly limited. When the pressing plate (310) descends, the waste solar panel may be pressed and secured between the pressing plate (310) and the transfer rollers (211) of the first transfer unit (210).

In this way, the transfer unit (200) in the lower part of the frame (100) and the pressing unit (300) in the upper part of the frame (100) may be formed. Thus, after precisely positioning the waste solar panel in a mixed direction of the first and second directions (for example, a diagonal direction) by the transfer unit (200), which includes the first transfer unit (210) and the second transfer unit (220), the waste solar panel may be pressed and secured by the pressing unit (300) and any sealant or other foreign substances may be removed.

The present invention may further include the first stopper unit (410) and the second stopper unit (420) to more accurately adjust the position of the waste solar panel. The first stopper unit (410) is configured to support the lateral sides of the waste solar panel in the second direction (identical to the second edge [A2] and the third edge [A3] in FIG. 8), while the second stopper unit (420) is configured to support the lateral sides of the waste solar panel in the first direction (identical to the first edge [A1] and the fourth edge [A4] in FIG. 8). The structures and functions of these units may be as follows.

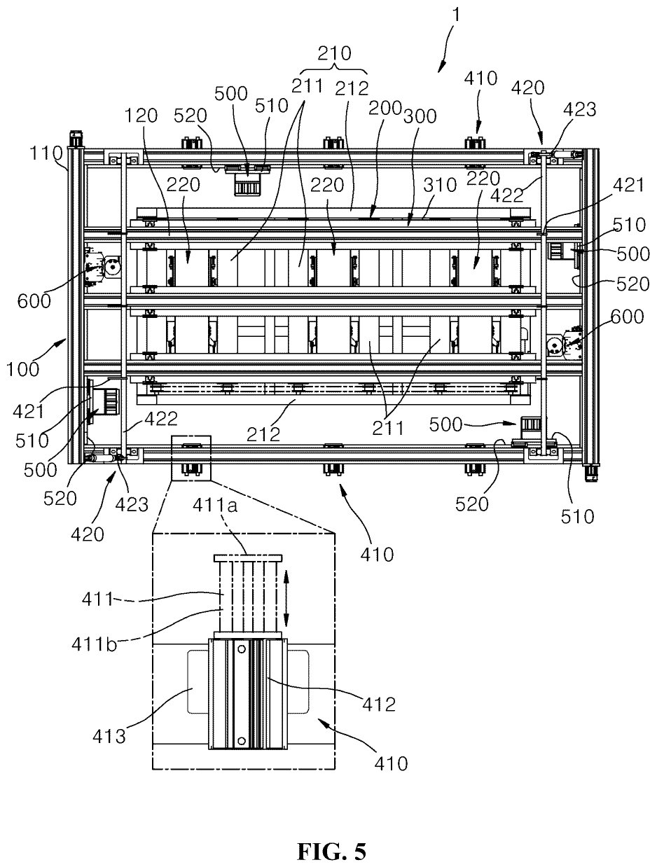

FIG. 4 is a side view of the sealant removing apparatus of FIG. 3, and FIG. 5 is a plan view of the sealant removing apparatus of FIG. 2.

Hereinafter, with reference to FIGS. 3 to 5, the structures of the first stopper unit (410), the second stopper unit (420), and the blade unit (500) are described in more detail. Referring to FIGS. 3 and 5, the first stopper unit (410) is installed on both sides of the first transfer unit (210). As shown in FIGS. 3 and 5, the first stopper unit (410) may be arranged in multiple units spaced apart in the second direction on both sides of the first transfer unit (210). Each first stopper unit (410) may be selectively positioned to support either the second edge or the third edge of the waste solar panel.

The first stopper unit (410) is formed so that at least a portion is movable in the second direction. With such a movable structure, the lateral sides of the waste solar panel in the second direction can be supported. Referring to FIG. 5, the first stopper unit (410) may comprise a first support portion (411) for supporting the side of the waste solar panel and an actuating portion (412) for telescopically expanding the first support portion (411) in the second direction. If necessary, a supporting member (refer to 413 in FIG. 3) may be provided for height adjustment.

The first support portion (411) may comprise a planar support plate (411a) and a connecting bar (411b) that is vertically connected to the support plate (411a), as shown in FIG. 5. The connecting bar (411b) may be drawn into or withdrawn from the actuating portion (412) and is extendable. The first support portion (411) may be formed in a structure where the connecting bar (411b) is telescopically coupled to the actuating portion (412).

The actuating portion (412) may include a structure for linearly driving the connecting bar (411b) (for example, a cylinder, gear, ball screw, or the like). Since various mechanisms that allow the first support portion (411) to telescope may be applied, numerous modifications are possible as long as they remain within the telescoping range. In other words, the driving structure of the actuating portion (412) is not particularly limited to one specific form.

When the blade unit (500) removes sealant (and/or other foreign substances) from the waste solar panel, the actuating portion (412) may separate the first support portion (411) from the waste solar panel (refer to the operation diagrams in (a) of FIG. 10 and (a) of FIG. 12). That is, by telescopically moving the first support portion (411) in the second direction, the side of the waste solar panel can either be supported or not. In particular, the retraction of the first support portion (411) by the actuating portion (412) allows the blade unit (500) to move more smoothly along the edge of the waste solar panel. The sealant removal operation using this mechanism will be described later in greater detail.

On the other hand, referring to FIGS. 3 and 4, the second stopper unit (420) may include a rotation shaft (422) arranged parallel to the second direction, a second support portion (421) that is coupled to the rotation shaft (422) and operates in response to its rotation, and a driving unit (423) for driving the rotation shaft (422). As shown in FIG. 4, the second stopper unit (420) may be arranged in multiple units spaced apart in the first direction on both sides of the first transfer unit (210). Each second stopper unit (420) may be selectively positioned to support either the first edge or the fourth edge of the waste solar panel.

The second support portion (421) is coupled to the rotation shaft (422) and is driven by its rotation. As the rotation shaft (422) rotates, the second support portion (421) may support the lateral side of the waste solar panel or separate from it. In FIG. 4, for instance, the second support portion (421) on the left is shown in a rotated position to support the side of the waste solar panel, while the second support portion (421) on the right is rotated so as to separate from the waste solar panel.

Thus, the second stopper unit (420) operates independently, so that it may either support the side of the waste solar panel or withdraw as needed. In particular, by using the second support portion (421) connected to the rotation shaft (422) which changes its position upon rotation, the lateral sides of the waste solar panel in the first direction can be effectively supported and easily disengaged when necessary.

Referring again to FIG. 3, a single second stopper unit (420) may include a plurality of second support portions (421) coupled on the rotation shaft (422). These multiple second support portions (421) may be spaced apart along a single rotation shaft (422) and may rotate together at the same angle. If height adjustment is required, the second stopper unit (420) may also be arranged on a supporting member (424) that supports the rotation shaft (422).

As shown in FIG. 4, the second support portion (421) may be formed in the shape of a hook with an engagement hook (421a) at its end. For example, when the second support portion (421) rotates downward, the hook (421a) may engage with and secure the side of the waste solar panel. Conversely, if the second support portion (421) rotates upward such that the hook (421a) moves to a position that does not intersect with the waste solar panel, the hook (421a) does not engage. Through such operation, during the movement of the blade unit (500), the second support portion (421) can be raised to avoid interference with the blade unit (500). The associated operation will be described in greater detail later.

As shown in FIGS. 3 and 4, the second support portion (421) may include a driving unit (423) for rotating the rotation shaft (422). The driving unit (423) may, for example, include a cylinder (423a) and an arm (423b) that is radially protruding from the rotation shaft (422) connected to the cylinder (423a). Thus, by means of the telescopic action of the cylinder (423a), the arm (423b) can be rotated, and the rotational force of the arm (423b) can drive the rotation shaft (422).

The connection between the arm (423b) and the cylinder (423a) may be formed with a joint so that it is foldable. The other end of the cylinder (423a) that is not coupled to the arm (423b) may also be fixed to the frame (100) via a joint, thereby allowing an angular change. Consequently, as the cylinder (423a) undergoes its telescopic motion, its angle is appropriately modified, thereby enabling the arm (423b) to be rotated.

With this structure, the amount of rotation of the rotation shaft (422) can be adjusted, allowing the position of the second support portion (421) to be finely tuned according to the rotational amount. For example, as illustrated on the left side of FIG. 4, by contracting the cylinder (423a) to pull the arm (423b), the second support portion (421) can be adjusted to descend to an appropriate position; conversely, as shown on the right side of FIG. 4, by extending the cylinder (423a) to push the arm (423b), the second support portion (421) can be adjusted to ascend to an appropriate position.

In addition, by changing the lengths of the cylinder, the arm, and the second support portion, the rotational position of the second support portion (421) can be adjusted in a more diverse manner. Hence, the contact position between the second support portion (421) and the first direction side of the waste solar panel can be altered as desired, thereby enabling a more precise adjustment of the position in the first direction. Thus, the structure is not particularly limited to the illustrated form of the second stopper unit (420). In this manner, the first stopper unit (410) and the second stopper unit (420) may be formed.

The blade unit (500) is configured as follows.

Referring to the enlarged views in FIGS. 3 and 4, the blade unit (500) includes a plurality of blades. The blade unit (500) may include at least two sequentially arranged blades, namely, a first blade (501) and a second blade (502). The first blade (501) moves along an edge of the waste solar panel to scrape and remove the sealant (and/or other foreign substances, such as those attached to the surface-particularly the front glass surface) from the waste solar panel, while the second blade (502) is arranged at the rear of the first blade (501), also moves along the edge of the waste solar panel, and removes residual sealant (and/or other foreign substances) remaining after passage of the first blade (501).

Preferably, as in the present embodiment, the blade unit (500) further includes a third blade (503) which is arranged at the rear of the second blade (502) and removes residual sealant (and/or other foreign substances) remaining after the second blade (502) has passed. In this case, the angles between the surface of the waste solar panel and the first blade (501), the second blade (502), and the third blade (503) may gradually decrease (refer to the enlarged view in FIG. 12).

That is, by utilizing a multi-blade structure, the blade unit (500) is capable of very effectively scraping and removing the sealant and other foreign substances. Each blade (from the first blade to the third blade) may be formed such that at least one of the angle between the waste solar panel's surface and the blade and the depth by which the waste solar panel is pressed is configured differently, thereby progressively increasing the scraping force.

For example, in the present embodiment, the angle between the first blade (501) and the surface of the waste solar panel (refer to A in FIG. 12) may be set at 45°, the angle between the second blade (502) and the waste solar panel (A) may be set at 40°, and the angle between the third blade (503) and the waste solar panel (A) may be set at 30°, thereby sequentially decreasing. By employing such a multi-blade blade unit (500), the sealant and other foreign substances can be effectively removed from the four edges of the waste solar panel.

The blade unit (500) may, for example, include a body (504) for fixing the plurality of blades (from the first to the third blades) and a drive structure for moving the body (504) in parallel along the edge of the waste solar panel. The drive structure may, for instance, include a horizontal rail (refer to 520 in FIGS. 3 and 5) arranged on the frame (100) and a slider (510) that is slidably coupled to the horizontal rail (520).

That is, the blade unit (500) may be formed in a structure in which the body (504) is coupled to a slider (510) that moves in parallel along the horizontal rail (520). Referring to FIG. 5, the horizontal rail (520) may be arranged in at least four units corresponding to the four edges of the waste solar panel around the first transfer unit (210). Consequently, each blade unit (500) may move along the edge of the waste solar panel to scrape off residual sealant and other foreign substances.

That is, four blade units (500) may be arranged, one for each edge of the waste solar panel, and they can operate independently. The four blade units (500) move in parallel along the first edge (A1 in FIG. 8), the second edge (A2 in FIG. 8), the third edge (A3 in FIG. 8), and the fourth edge (A4 in FIG. 8) of the waste solar panel, respectively, to remove sealant and/or various foreign substances.

Between the body (504) and the slider (510) of the blade unit (500), a lifting unit (refer to 511 in FIG. 3) may be provided so that the blades of the blade unit (500) are brought into close contact with the waste solar panel only during the sealant removing operation. The lifting unit (511) may be formed, for example, with a cylinder arranged vertically between the slider (510) and the body (504).

With such a structure, the blade unit (500) can move along the four edge portions of the waste solar panel and operate simultaneously. In particular, by combining the cross-movement structure of the first transfer unit (210) and the second transfer unit (220) in the first and second directions and the side support structure provided by the first stopper unit (410) and the second stopper unit (420) in the first and second directions, even waste solar panels with different dimensions can be precisely positioned in a diagonal direction to enable simultaneous processing of at least two edges.

In the present embodiment, the sealant removing apparatus (1) operates such that two adjacent blade units (500) move along the edge of the waste solar panel—where that edge is configured in a “ [symbol] ” or “ [symbol] ” shape to remove sealant (and/or other foreign substances), and thereafter the remaining two blade units (500) move along the edge (formed in a “ [symbol] ” or “ [symbol] ” shape) of another portion of the waste solar panel to remove sealant (and/or other foreign substances) (see the operating diagrams of (a) of FIG. 10 and (a) of FIG. 12). Here, the “ [symbol] ” shape may refer to an inverted L shape, and the “ [symbol] ” shape may refer to an L shape, and the same interpretation applies hereinafter.

More specifically, such operation is carried out by first transferring the waste solar panel in one direction by means of the first transfer unit (210) and the second transfer unit (220) so that the blade units (500) move along an edge configured in a “ [symbol] ” or “ [symbol] ” shape to remove the sealant; thereafter, the first transfer unit (210) and the second transfer unit (220) move the waste solar panel in a diagonal direction (refer to the diagonal arrow in (a) of FIG. 11) so that the blade units (500) move along an edge configured in a “ [symbol] ” or “ [symbol] ” shape to remove the sealant (and/or other foreign substances). After describing the trimming unit, the operation of the present invention will be explained in further detail.

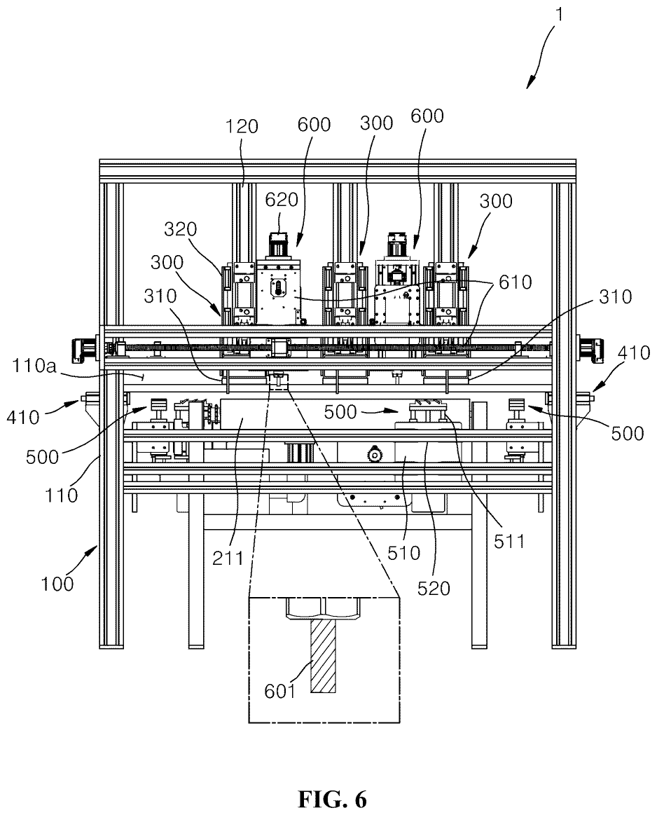

FIG. 6 is a front view of the sealant removing apparatus of FIG. 2. This front view is based on the portion where the aforementioned inlet is formed.

Referring to FIGS. 3 and 6, the sealant removing apparatus (1) may further include a trimmer unit (600) that forms a step at the end of the waste solar panel. With the trimmer unit (600), the end of the film layer (refer to Ab in FIG. 10) can be pre-machined so that peeling is facilitated. This prepares the waste solar panel for an easier subsequent peeling process, and by performing this step first during sealant removal, the inter-process connectivity is further enhanced. The trimmer unit (600) may be arranged on the frame (100) and spaced in the first direction so as to overlap internally with the inner sides of the waste solar panel on both sides in the first direction (i.e., corresponding to the aforementioned first and fourth edges).

The waste solar panel is arranged such that its glass plate (refer to Aa in FIG. 10) is in contact with the transfer unit (see 200 in FIG. 3), while the film layer—which is bonded to the glass plate by means of a multi-laminated structure (including solar cells, encapsulant, and backsheet, for example, as shown in Ab of FIG. 10)—is in contact with the pressing unit (300). Therefore, the trimmer unit (600) is disposed on the upper side of the waste solar panel so that an end mill (601), for example, shown in FIG. 6, is lowered from above to perform a trimming operation from the top toward the bottom.

The trimmer unit (600) is capable of moving along the edge of the waste solar panel to remove the end portion of the film layer (see the operating diagrams of (b) of FIG. 10 and (b) of FIG. 12). For this purpose, the trimmer unit (600) may include both a horizontal drive unit (610) and a vertical drive unit (620) as exemplified in FIG. 6. The vertical drive unit may be formed, for example, by arranging a telescopic cylinder vertically, while the horizontal drive unit may be formed, for example, by a ball screw structure arranged in the horizontal direction.

Accordingly, the sealant removing apparatus (1) can operate as follows. The subsequent description, with reference to FIGS. 7 to 12, explains the operating process of the sealant removing apparatus in further detail.

FIG. 7 is a plan view of the sealant removing apparatus of FIG. 2 with the upper structure removed and FIG. 8 is a plan view illustrating the panel feeding operation of the waste solar panel in the apparatus of FIG. 7.

In FIG. 7 which is the plan view of the sealant removing apparatus, the relative positions between the waste solar panel and the lower structure (i.e., the bed, transfer unit, and the first and second stopper units) are illustrated, with the upper structure (upper bridge, pressing unit, etc.) omitted. In the subsequent operational diagrams (FIGS. 8 to 12), the planar position of the waste solar panel is illustrated based on FIG. 7.

The waste solar panel (A) may be introduced into the sealant removing apparatus in the direction indicated in FIG. 8. The entering direction of the waste solar panel (A) may correspond to the transfer direction of the first transfer unit (210)(see FIG. 3). For example, the waste solar panel (A), which is fed into the sealant removing apparatus via an entry conveyor (refer to 10 in FIG. 1), may enter the apparatus through the aforementioned inlet (refer to 110a in FIG. 3).

As shown, the waste solar panel (A) is rectangular and has four edges. In practical terms, the four edges of the waste solar panel (A) are equivalent to its four sides (in the plan view, represented as the four sides of a rectangle). In the drawings, the lateral sides in the first direction of the waste solar panel (A) are indicated as the first edge (A1) and the fourth edge (A4), while the lateral sides in the second direction are designated as the second edge (A2) and the third edge (A3).

For example, the waste solar panel (A) may be introduced such that the first edge (A1) faces the front of the sealant removing apparatus. Thus, once the waste solar panel (A) is introduced into the sealant removing apparatus, all four edges can have their sealant and foreign substances removed after only two position adjustment operations. In other words, regardless of the size of the waste solar panel (A), the present invention can process all four edges with only two positional adjustments.

FIG. 9 includes a plan view of the first positioning operation of the waste solar panel using the apparatus of FIG. 7 and a partial cross-sectional view of the apparatus of FIG. 2 and FIG. 10 includes a plan view and partial cross-sectional view showing the sealant removing and trimming operations after the first positioning operation using the apparatus of FIGS. 7 and 2.

First, as shown in (a) of FIG. 9, the waste solar panel (A) is adjusted in position so that two adjacent edges (namely, the first edge [A1] and the second edge [A2]) overlap with the blade units (500) arranged at those edges (this constitutes the first position adjustment operation). Since the first transfer unit (210) and the second transfer unit (220) can move the waste solar panel (A) in the first and second directions (which are mutually perpendicular), the two edges that are arranged at right angles (i.e., the first edge [A1] and the second edge [A2]) can be pushed diagonally such that they overlap with the blade units (500) positioned at those edges.

If the dimensions of the waste solar panel (A) are larger than those shown, the blade units (500) arranged on all four edges may already overlap with the waste solar panel (A) without such an adjustment operation. However, even when the waste solar panel (A) is smaller than the dimensions shown, by adjusting the position of the waste solar panel (A) in mutually perpendicular directions using the first transfer unit (210) and the second transfer unit (220), at least two adjacent edges can be overlapped with the blade units (500) arranged at those edges.

At this time, as shown in (b) of FIG. 9, the pressing unit (300) is maintained in an elevated state, not contacting the waste solar panel (A), while the transfer means (221) of the second transfer unit (220) is raised such that it contacts the waste solar panel (A). The transfer means (221) can move to a position higher than or lower than the top of the transfer rollers (211) of the first transfer unit (210) by virtue of the aforementioned lifting means (refer to 222 in FIG. 3), thereby moving the waste solar panel (A) in the second direction.

When the first transfer unit (210) moves to a position lower than the top of its transfer rollers (211), the transfer rollers (211) of the first transfer unit (210) are capable of moving the waste solar panel (A) in the first direction (which is perpendicular thereto), so that by combining the movements, the waste solar panel (A) can be moved diagonally as shown in (a) of FIG. 9. The transfer means (221) may repeatedly perform its lifting (vertical) movement during the position adjustment.

At this stage, the waste solar panel (A) can be fixed more precisely by the first stopper unit (410) and the second stopper unit (420). For instance, as shown in (a) of FIG. 9, the first stopper unit (410) extends its first support portion (411) so as to support the side of the waste solar panel (that is, the second edge [A2]), while, as shown in (b) of FIG. 9, the second stopper unit (420) rotates its second support portion (421) downward so as to support the side of the waste solar panel (that is, the first edge [A1]). Each of these support members is positioned forward of the waste solar panel (in FIG. 9, toward the lower left) so as to restrict the movement of the waste solar panel (A).

The second support portion (421) may prevent movement by engaging its terminal hook (421a) with the edge of the waste solar panel (A). The second stopper unit that does not support the edge (the first edge [A1]) may have its second support portion (421) raised so as to avoid contact with the waste solar panel (A). In this way, the positions of at least two adjacent edges (the first edge [A1] and the second edge [A2]) of the waste solar panel (A) can first be adjusted so that they overlap with the blade units (500).

As shown in (a) of FIG. 10, after this position adjustment, the two blade units (500) corresponding to the two adjacent edges (the first edge [A1] and the second edge [A2]) move along the edge to remove the sealant and/or other foreign substances. For example, the two blade units (500) located along the adjacent edges (configured in a “ [symbol] ” shape) of the waste solar panel (A) remove the sealant and/or other foreign substances as they move along the edge.

At this time, as shown in (b) of FIG. 10, the pressing unit (300) descends to press and secure the waste solar panel (A), while the first stopper unit (410) and the second stopper unit (420) return to their original positions. That is, the waste solar panel (A), whose position has been adjusted, is first fixed by the pressing plate (310) descending, and then the first stopper unit (410) and the second stopper unit (420) are withdrawn from the movement path of the blade units (500) so that the sealant removal operation can be performed.

As illustrated in the enlarged view of FIG. 10, the waste solar panel (A) is arranged such that its glass plate (Aa) faces downward and the attached film layer (Ab) faces upward. Therefore, the blade units (500) are raised by the aforementioned lifting unit (refer to 511 in FIG. 3) so that they are brought into close contact with the glass plate (Aa). In this state, as shown in (a) of FIG. 10, the blade units (500) move along the edge while in contact with the glass plate (Aa) to cleanly remove the sealant and/or other foreign substances attached to the glass plate (Aa) at that edge.

In this manner, while the blade units (500) remove the sealant, the trimmer unit (600) forms a step at the end of the film layer. In other words, the trimmer unit (600) is lowered by the aforementioned vertical drive unit (refer to 620 in FIG. 6) and, with an end mill (601), contacts the film layer (Ab) to trim (remove) its end portion. Since the trimmer unit (600) is also capable of horizontal movement by means of the aforementioned horizontal drive unit (refer to 610 in FIG. 6), it can move along the edge (i.e., the first edge [A1]) of the waste solar panel (A) to remove the end portion of the film layer.

In this way, removal of the sealant and foreign substances from any two adjacent edges (the first edge [A1] and the second edge [A2]) of the waste solar panel (A) can first be performed, and a trimming operation on the film layer (Ab) can also be carried out. Meanwhile, the remaining edge operations corresponding to the second position adjustment operation are performed as follows.

FIG. 11 includes a plan view of the second positioning operation of the waste solar panel using the apparatus of FIG. 7 and a partial cross-sectional view of the apparatus of FIG. 2 and FIG. 12 includes a plan view and partial cross-sectional view showing the sealant removing and trimming operations after the second positioning operation using the apparatus of FIGS. 7 and 2.

The work on the remaining two edges (the third edge [A3] and the fourth edge [A4]) can be carried out symmetrically to the process described above. In this case, the movement direction of the waste solar panel is reversed relative to the earlier movement.

To work on the remaining edges, as shown in (a) of FIG. 11, the position of the waste solar panel (A) is adjusted in the reverse direction so that the remaining two edges (the third edge [A3] and the fourth edge [A4]) are again overlapped with the corresponding blade units (500) (this constitutes the second position adjustment operation). At this time, the drive directions of the first transfer unit (210) and the second transfer unit (220) may be reversed relative to those in FIG. 9. Through this, the remaining two edges (i.e., the third edge [A3] and the fourth edge [A4]), which are arranged at right angles, can be pushed diagonally in the reverse direction, as shown in (a) of FIG. 11, so that they overlap with the blade units (500) positioned at those edges.

As shown in (b) of FIG. 11, during this second position adjustment operation the pressing unit (300) is raised so that it does not contact the waste solar panel (A), while the transfer means (221) of the second transfer unit (220) is raised to contact the waste solar panel (A). The transfer means (221) may, as before, move to a position either above or below the top of the transfer rollers (211) of the first transfer unit (210) by means of the lifting means, thereby moving the waste solar panel (A) in the second direction.

Accordingly, even in this second adjustment, when the first transfer unit (210) moves to a position lower than the top of its transfer rollers (211), those rollers can move the waste solar panel (A) in the first direction, so that by combining these movements a reverse diagonal motion of the waste solar panel (A) is achieved as shown in (a) of FIG. 11.

At this stage, the waste solar panel (A) is further fixed in a precise position by the first stopper unit (410) and the second stopper unit (420). For example, as shown in (a) of FIG. 11, the first stopper unit (410) extends its first support portion (411) to support another side of the waste solar panel (that is, the third edge [A3]), while, as shown in (b) of FIG. 11, the second stopper unit (420) rotates its second support portion (421) downward to support yet another side of the waste solar panel (that is, the fourth edge [A4]). In this manner, by positioning each stopper unit at the front of the waste solar panel (in FIG. 11, toward the upper right) so as to contact it, the movement of the waste solar panel (A) is restrained.

At this time, the second support portion (421) may prevent movement by means of its terminal engagement hook (421a) engaging with the edge of the waste solar panel (A). Additionally, the second stopper unit that does not support the edge (here, the fourth edge [A4]) may have its second support portion (421) raised so that it does not contact the waste solar panel (A). In this way, the positions of the remaining two edges (the third edge [A3] and the fourth edge [A4]) are adjusted so that they overlap with the blade units (500).

Thus, after this position adjustment, as shown in (a) of FIG. 12, the remaining two blade units (500) arranged at the remaining two edges (the third edge [A3] and the fourth edge [A4]) move along the edge, quickly removing the sealant and/or other foreign substances. For example, as shown, the remaining two blade units (500) may be arranged along an edge configured in a “ [symbol] ” shape (in the case of the remaining edges [A3] and [A4]) to remove the sealant and/or other foreign substances.

During the sealant removal operation, as shown in (b) of FIG. 12, the pressing unit (300) is again lowered to press and secure the waste solar panel (A), while the first stopper unit (410) and the second stopper unit (420) return to their original positions. That is, the waste solar panel (A) whose position has been adjusted is first fixed by the descending pressing plate (310), and then the stopper units are withdrawn from the movement path of the blade units (500) so that the sealant removal operation can be performed.

Also, the blade units (500) are raised by the lifting unit (refer to 511 in FIG. 3) so that they are brought into close contact with the glass plate (Aa) of the waste solar panel (A). Thus, as shown in (b) of FIG. 12, the blade units (500), while moving along the edges in close contact with the glass plate (Aa), cleanly remove the sealant and/or other foreign substances attached to the glass plate (Aa) along that edge.

While the blade units (500) are engaged in removing the sealant, the trimmer unit (600) forms a step in the end portion of the film layer (Ab) at the corresponding edge (here, the fourth edge [A4]) as described above. However, if the trimming operation is sufficiently achieved by processing only one edge, the trimming work may be omitted in either the operation shown in FIG. 10 or FIG. 12.

Through this operation, sealant and other foreign substances can also be effectively removed from the remaining two edges (the third edge [A3] and the fourth edge [A4]) of the waste solar panel (A). That is, by sequentially performing the sealant removal operations on the four edges of the waste solar panel (A) through the first position adjustment operation shown in FIG. 9 and the second position adjustment operation shown in FIG. 11, the remaining sealant and other foreign substances on all four edges of the waste solar panel can be quickly and effectively removed.

In particular, during these operations the arrangement of the blades in the blade units (500) produces an enhanced effect in removing the sealant. As illustrated in the enlarged view of FIG. 12, the first blade (501), second blade (502), and third blade (503) are configured such that the angle formed with the surface of the waste solar panel (specifically, with the glass plate (Aa)) gradually decreases, thereby sequentially applying stronger pressure on the contact surface. Thus, even if some sealant escapes removal by the front blade, it is more forcefully contacted and removed by the subsequent blades. As a result, even fine residues of sealant, other foreign substances, or residual impurities can be removed very effectively.

Meanwhile, the first position adjustment operation shown in FIG. 9 and the second position adjustment operation shown in FIG. 11 may be performed in reverse order, and the adjacent edges to be processed simultaneously may also be changed in other embodiments. Therefore, the present embodiment is merely one example of a method in which two adjacent edges of the waste solar panel are first processed in a “ [symbol] ” or “ [symbol] ” configuration and then, after a position adjustment, the remaining two edges are processed in a “ [symbol] ” or “ [symbol] ” configuration. The present embodiment should not be construed as limiting the technical concept of the invention. In this way, by using a plurality of blade units formed with multi-blade structures, the removal of sealant and other substances from the four edges of the waste solar panel can be performed.

The embodiments described above with reference to the accompanying drawings are merely illustrative examples, and those skilled in the art can readily envisage various modifications and changes within the scope of the present invention without departing from its essential teachings.

[Explanation of Reference Numerals]

| | |
|---|---|
| 1: Waste solar panel | |
| sealant removing apparatus | |
| 10: Entry conveyor | 20: Discharge conveyor |
| 100: Frame | 110: Bed |
| 120: Upper bridge | 121: Vertical bar |
| 200: Transfer unit | 210: First transfer unit |
| 211: Transfer rollers | 212: Horizontal support |
| 220: Second transfer unit | 221: Transfer means |
| 222: Lifting means | 300: Pressing unit |
| 310: Pressing plate | 320, 510: Sliders |
| 330: Lifting drive unit | 331, 423a: Cylinder |
| 332: Connecting rod | 410: First stopper unit |
| 411: First support portion | 411a: Support plate |
| 411b: Connecting bar | 412: Actuating portion |
| 420: Second stopper unit | 421: Second support portion |
| 421a: Engagement hook | 422: Rotation shaft |
| 423: Driving unit | 423b: Arm |
| 500: Blade unit | 501: First blade |
| 502: Second blade | 503: Third blade |
| 504: Body | 511: Lifting unit |
| 520: Horizontal rail | 600: Trimmer unit |
| 601: End mill | 610: Horizontal drive unit |
| 620: Vertical drive unit | A: Waste solar panel |
| Aa: Glass plate | Ab: Film layer |
| A1: First edge | A2: Second edge |
| A3: Third edge | A4: Fourth edge |

### INDUSTRIAL APPLICABILITY

The present invention is industrially applicable because it is effectively utilized for processing waste solar panels (including their dismantling for recycling). In particular, by uniformly treating the glass plate surface of waste solar panels prior to the peeling process, the present invention prevents breakage or damage to the glass during processing. This is advantageous from the perspective of resource recycling and circular economy.

1. A waste solar panel sealant removing apparatus, comprising:
a frame;
a transfer unit installed on the frame and configured to transfer the waste solar panel in a horizontal direction;
a pressing unit that descends from above the transfer unit and presses the waste solar panel to secure it; and
a blade unit comprising a first blade and a second blade, wherein the first blade is in close contact with the waste solar panel and moves along an edge of the waste solar panel to scrape and remove the sealant attached to its surface, and the second blade is arranged at the rear of the first blade, moves along the edge of the waste solar panel, and removes residual sealant remaining after passing the first blade.

2. The waste solar panel sealant removing apparatus of claim 1,
wherein the first blade and the second blade are configured such that at least one of the following—the angle formed between each blade and the surface of the waste solar panel, or the depth to which the waste solar panel is pressed—is formed differently between the first blade and the second blade.

3. The waste solar panel sealant removing apparatus of claim 2,
wherein the transfer unit comprises a first transfer unit composed of a plurality of transfer rollers for transferring the waste solar panel in a first direction, and at least one second transfer unit configured to transfer the waste solar panel in a second direction perpendicular to the first direction.

4. The waste solar panel sealant removing apparatus of claim 3, wherein the second transfer unit comprises a transfer means for transferring the waste solar panel in the second direction, and a lifting means for moving the transfer means up and down so as to raise the transfer means to a position higher than the top of the transfer rollers or lower than the top of the transfer rollers.

5. The waste solar panel sealant removing apparatus of claim 3,
further comprising a plurality of first stopper units that are installed on both sides of the first transfer unit, wherein at least a portion of each first stopper unit is movable in the second direction to support the lateral sides of the waste solar panel in the second direction.

6. The waste solar panel sealant removing apparatus of claim 5,
wherein each first stopper unit comprises a first support portion for supporting the side of the waste solar panel and an actuating portion for expanding or contracting the first support portion in the second direction, with the actuating portion separating the first support portion from the waste solar panel when the blade unit removes the sealant.

7. The waste solar panel sealant removing apparatus of claim 3,
further comprising a plurality of second stopper units for supporting the lateral sides of the waste solar panel in the first direction, each second stopper unit comprising a rotation shaft arranged parallel to the second direction, a second support portion coupled to the rotation shaft and configured to support the side of the waste solar panel as the rotation shaft rotates, and a driving unit for rotating the rotation shaft.

8. The waste solar panel sealant removing apparatus of claim 7,
wherein each second stopper unit rotates the rotation shaft to separate the second support portion from the waste solar panel when the blade unit removes the sealant.

9. The waste solar panel sealant removing apparatus of claim 3,
wherein four blade units are independently arranged at each edge of the waste solar panel such that two of the blade units located at adjacent edges move along edges arranged in a ‘ [symbol] ’ oe [symbol] shape to remove sealant, and thereafter the remaining two blade units move along edges arranged in a ‘ [symbol] ’ or ‘ [symbol] ’ shape to remove sealant.

10. The waste solar panel sealant removing apparatus of claim 9,
wherein after the first transfer unit and the second transfer unit transfer the waste solar panel in one direction so that the blade units move along edges arranged in a ‘ [symbol] ’ or ‘ [symbol] ’ shape to remove sealant, the first transfer unit and the second transfer unit then move the waste solar panel in a diagonal direction so that the blade units move along edges arranged in a ‘ [symbol] ’ or ‘ [symbol] ’ shape to remove sealant.

11. The waste solar panel sealant removing apparatus of claim 2,
wherein the blade unit further comprises a third blade that is arranged at the rear of the second blade and moves along the edge of the waste solar panel to remove residual sealant remaining after passing the second blade, and wherein the first, second, and third blades are configured such that the angle formed with the surface of the waste solar panel gradually decreases.

12. The waste solar panel sealant removing apparatus of claim 1,
wherein the waste solar panel is arranged such that the glass plate contacts the transfer unit and the film layer contacts the pressing unit, and further comprising a trimmer unit disposed on the upper side of the waste solar panel and configured to move along an edge of the waste solar panel to remove an end portion of the film layer.
